(19) United States
(12) Patent Application Publication
(10) Pub. No.: US 2008/0014679 A1
(43) Pub. Date: Jan. 17, 2008

(54) Packaging structure with protective layers and packaging method thereof

(75) Inventors: Lee-Cheng Shen, Hsinchu (TW); Shu-Ming Chang, Hsinchu (TW)

Correspondence Address: BIRCH STEWART KOLASCH & BIRCH, PO BOX 747, FALLS CHURCH, VA, 22040-0747, US

(73) Assignee: Industrial Technology Research Institute

(21) Appl. No.: 11/589,122

(22) Filed: Oct. 30, 2006

(30) Foreign Application Priority Data
Jul. 12, 2006 (TW) 095125542

(51) Int. Cl. H01L 21/00

(52) U.S. Cl. 438/106

(57) ABSTRACT

A packaging structure with protective layers and a packaging method thereof are provided. A protective layer is formed on the surface and the pre-dicing line of the wafer to protect the chip and the die during the wafer grinding process, so as to prevent the wafer from being damaged due to the collision during the transportation process, and thereby reinforcing the mechanical strength of the wafer and the chip, which is useful for the subsequent packaging process.

### CROSS-REFERENCE TO RELATED APPLICATIONS

This non-provisional application claims priority under 35 U.S.C. § 119(a) on Patent Application No(s). 095125542 filed in Taiwan, R.O.C. on Jul. 12, 2006, the entire contents of which are hereby incorporated by reference.

### BACKGROUND OF THE INVENTION

1. Field of Invention

The present invention relates to a packaging structure and a packaging method thereof, and more particularly, to a packaging structure with protective layers and a packaging method thereof.

2. Related Art

Wafers generate radiated grinding nicks during the grinding and polishing process, and the geometrical grinding nicks include countless tiny cracks and scratches, thus, the residual stress is generated to result in the breaking of the wafer. Moreover, tiny cracks are generated along the edge of the diced die while dicing the die, so as to cause the increasing of the residual stress and the stress concentration. The inappropriate die dicing process results in a structure with defects, which are also the reason for the breaking of the die and the reducing of the strength.

In order to reduce the breaking problem of the wafer during the packaging process, recently the dicing before grinding (DBG) process has been developed. Firstly, a dicing blade is used to slot at the active side of the wafer, wherein the dicing depth is approximately a bit deeper than the thickness of the finished die, and then, the grinding machine is used to grind the chip to separate the die. The advantage lies in that, the grinding process is the last step, so during the whole process, those that are processed and transmitted are relatively thick wafers, such that the breaking rate caused by the transmission error is reduced. Although the DBG process reduces the chipping of the die edge when the thinned wafer is directly diced, the problem of breaking the chip edge during the dicing or grinding process cannot be totally avoided as for the DBG process.

As for the wafer-level package (WLP) process, the wafer is taken as an object of the packaging process, instead of a single chip as in the conventional packaging. Because an underfill and a substrate are not required in the WLP process, the material cost and the time are greatly saved. However, during the process of taking and assembling the WLP bare die, the bare die is easily collided and generates cracks, thereby affecting the reliability of the subsequent assembly.

Furthermore, the chip in substrate package (CiSP) process is a packaging technique that does not require wire bonding and flip chip bumping, so that the connecting of the chip is achieved simultaneously and directly during the process of manufacturing a carrier plate, and by embedding the element, the packaging area is greatly reduced, and more high functional elements may be added into the remaining space, thereby increasing the whole packaging density of the product. However, during the process of internally burying the chip, and the process of taking out/putting in, fixing, and pressing the embedded die, the chip is easily broken.

In addition, recently, the structure of the chip mostly adopts a low dielectric constant material to reduce the time delay effect in a multi-layer metal interconnection. In order to achieve the low dielectric property, the low dielectric constant material mostly has a loose structure with an undesired mechanical strength, so the construction of the multi-layer metal lead formed by the low dielectric constant material is easily broken due to external stress caused by packaging processes, so as to result in disconnection and thereby damaging the operation of the element.

In order to protect the chip during the packaging process, U.S. Pat. No. 6,187,615 discloses a wafer level packaging method, wherein a reinforcing layer is provided to wrap around a solder ball, and a protective layer is formed at the chip edge. The protective layer is formed on the surface above the predicing line, thus, the chip edge is not totally wrapped by the protective layer after the dicing process has been finished.

Moreover, in order to protect the chip edge during the dicing process, U.S. Patent Publication No. 2005/0110156 A1 discloses a method for protecting the chip edge of a wafer level packaging, wherein the wafer is adhered to a synthetic resin substrate of the strengthened fiber, then, the wafer is diced to form a cut, a polymer layer is formed at the position of the cut to protect the chip edge, and the wafer is totally diced off to form a plurality of chips. However, the polymer served as the protective layer only forms on the chip edge, thus, it does not provide protections for the part except the chip edge.

However, during various packaging processes of the chip, the die is easier broken or the low dielectric constant material is easily damaged etc., thus, it is an important issue to provide a full protection method, so as to make the chip not easy to generate die breaking, reinforce the strength, and maintain the completeness of the low dielectric constant material.

### SUMMARY OF THE INVENTION

In view of the problems in the prior art, the present invention provides a packaging structure with protective layers and a packaging method thereof, wherein the protective layer is used to fill or cover a die to reinforce the mechanical strength of an edge and a side wall of the die. Moreover, the protective layer is filled in a surface and a predicing line of the wafer, so as to serve as a buffer layer for the mechanical stress and provide protections for the chip and the die during the wafer grinding process.

In the wafer level packaging method with protective layers according to the present invention, firstly, a wafer is provided, which has a first surface and a second surface. Next, a plurality of notches is formed in the first surface, and a first protective layer is formed on the first surface and in each notch. Then, the wafer is thinned on the second surface, thus making the first protective layer in each notch be exposed at the second surface. Finally, each notch is diced to form a plurality of chips. The first protective layer located on the first surface connects to the first protective layer in each notch and at least covers a part of the area of the first surface. Moreover, an alternative in the present invention, a second protective layer is formed before each notch is diced to form the plurality of chips. The second protective layer is located on the second surface and connects to the first protective layer in each notch, and at least covers a part of the area of the second surface.

The wafer level packaging structure with protective layers fabricated through the above method comprises a wafer and a first protective layer. The wafer has a first surface, a second surface, and a plurality of notches. The first protective layer is located on the first surface and in each notch, and the first protective layer is exposed to the second surface through each notch. The first protective layer located on the first surface connects to the first protective layer in each notch and at least covers a part of the area of the first surface. Moreover, the wafer level packaging structure with a protective layer further comprises a second protective layer located on the second surface, which connects to the first protective layer through each notch and at least covers a part of the area of the second surface.

Furthermore, the chip level packaging structure with protective layers formed after dicing the wafer level packaging structure comprises a chip and a first protective layer. The chip has a first surface and a second surface and the first protective layer is located on the first surface and at least an edge of the chip that connects the first surface with the second surface. The first protective layer located on the first surface connects to the first protective layer located at the edge. The first protective layer on the first surface at least covers a part of the area of the first surface. Furthermore, the chip level packaging structure with protective layers further comprises a second protective layer located on the second surface, which connects to the first protective layer on the edge and at least covers a part of the area of the second surface.

Both of the first and second protective layers are high molecular polymer layers. In addition, the first surface of the wafer further has a plurality of lead pads, a plurality of electrical channels is formed on each lead pad, and then, a plurality of solder balls can be further formed on each electrical channel.

The protective layer of the present invention is used to be filled in the predicing line or covers the edge and the surface of the die, so as to provide protections for the chip and the die during the wafer grinding process, and prevent the wafer from being damaged due to the collision during the transportation process, and thereby reinforcing the mechanical strength of the wafer and the chip, which is useful for the subsequent packaging process.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only, which thus is not limitative of the present invention, and wherein:

FIG. 1 is a view of a packaging structure according to a first embodiment of the present invention;

FIGS. 2A to 2G are schematic views of the flow of a packaging method according to the first embodiment of the present invention;

FIGS. 3A to 3B are schematic views of a second embodiment of the present invention;

FIGS. 4A to 4B are schematic views of a third embodiment of the present invention;

FIGS. 5A to 5B are schematic views of a fourth embodiment of the present invention;

FIGS. 6A to 6B are schematic views of a fifth embodiment of the present invention;

FIGS. 7A to 7B are schematic views of a sixth embodiment of the present invention; and

FIGS. 8A to 8B are schematic views of a seventh embodiment of the present invention.

### DETAILED DESCRIPTION OF THE INVENTION

In order to further understand the objective, construction, feature, and function of the present invention, it is illustrated below in detail through the embodiments. The above description of the content of the present invention and the following detailed description are intended to demonstrate and illustrate the principle of the present invention, and thereby providing a further explanation of the claims of the present invention.

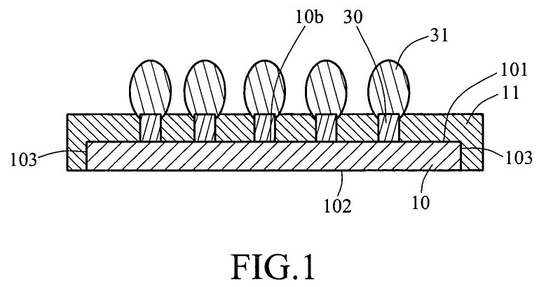

Referring to FIG. 1, it is a view of a packaging structure according to a first embodiment of the present invention. As shown in FIG. 1, the chip level packaging structure includes a substrate 10 and a protective layer 11. The substrate 10 has a first surface 101 and a second surface 102. The protective layer 11 is located on the first surface 101 and a plurality of edges 103 of the substrate 10 that connects the first surface 101 with the second surface 102. The protective layer 11 on the first surface 101 covers a part of the area of the first surface 101. The protective layer 11 of the present invention is made by a high molecular polymer, and used for protecting the substrate 10 from being cracked or damaged, and also used for protecting the low dielectric constant material contained in the first surface 101. Moreover, the first surface 101 has a plurality of lead pads 10b. The lead pads 10b are formed on the conducting area of the first surface 101 after the redistribution of the leads. A plurality of electrical channels 30 is formed on each lead pad 10b. A plurality of solder balls 31 is formed on each electrical channel 30. Therefore, the protective layer 11 on the first surface 101 also provides the function of a passivation layer. Moreover, the solder balls 31 are used for the subsequent packaging process such as the flip chip bonding.

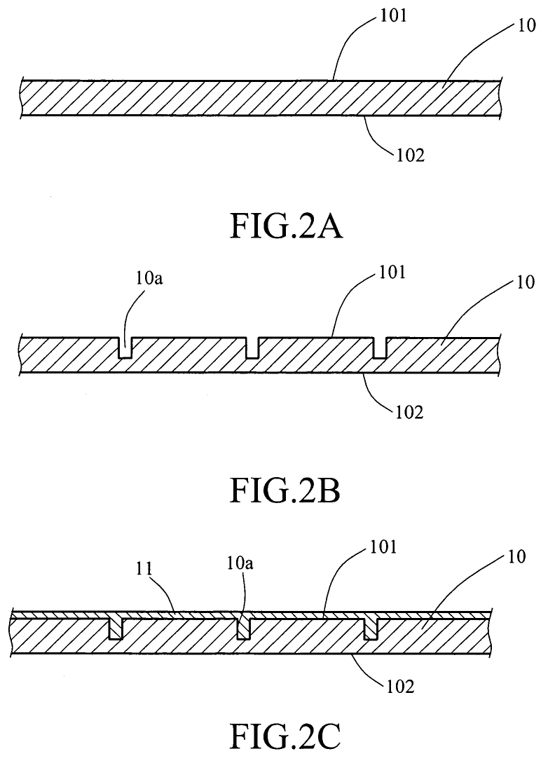

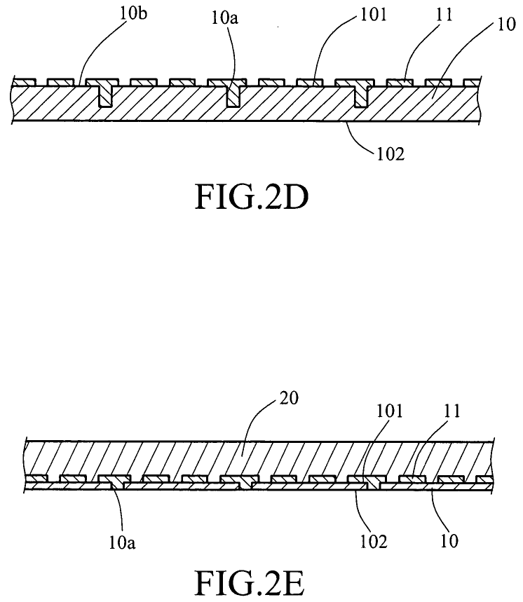

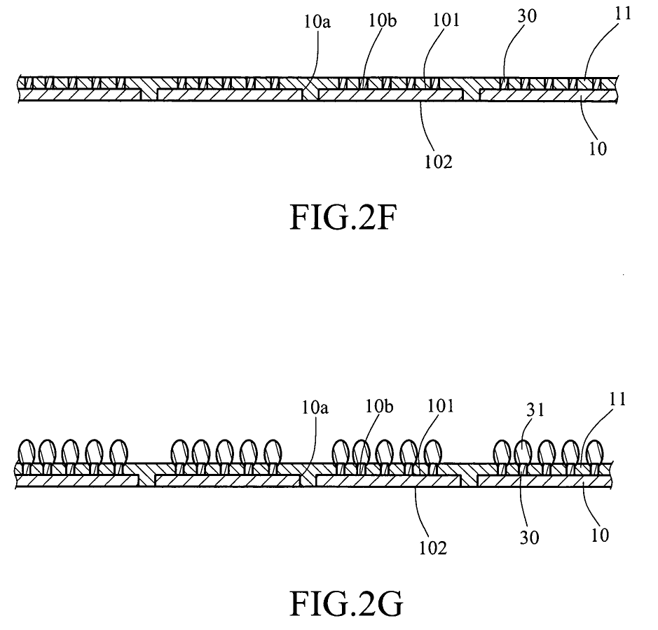

Referring to FIGS. 2A to 2G, the packaging method of the first embodiment is illustrated in detail. As shown in FIG. 2A, a wafer level substrate 10 having a first surface 101 and a second surface 102 is provided. The substrate 10 is a silicon wafer, and the first surface 101 has a circuit wiring (not shown). Next, as shown in FIG. 2B, a plurality of notches 10a is formed on the first surface 101, wherein the depth of the notch 10a is slightly deeper than the thickness of the finally finished die. Then, as shown in FIG. 2C and FIG. 2D, a protective layer 11 is formed on the first surface 1101 and in each notch 10a, wherein first, the high molecular polymer is covered on the first surface 101 by way of deposition, printing, or coating, and it is filled within each notch 10a, so as to form the protective layer 11, as shown in FIG. 2C. Therefore, the cracks generated while dicing the notch 10a are filled up by the high molecular polymer, so as to prevent the cracks from being continuously expanded during the subsequent packaging process and thereby achieving the function of protecting the die. Then, an etching process is performed on the protective layer 11, so as to expose the plurality of lead pads 10b of the first surface 101, as shown in FIG. 2D. The pattern of the finally formed protective layer 11 is that the protective layer 11 on the first surface 101 connects to the protective layer 11 in the notch 10a and covers the area of the first surface 101 except the lead pads 10b.

As shown in FIG. 2E, the second surface 102 of the substrate 10 is thinned, such that the protective layer 11 in the notch 10a is exposed at the second surface 102. Firstly, a carrier 20 is used to absorb the first surface 101 of the substrate 10, then, the second surface 102 is used to thin the substrate 10 by way of grinding or etching, and after the thinning process has been finished, the protective layer 11 in the notch 10a exposes at the second surface 102. The protective layer 11 fills up the cracks generated while dicing the notch 10a, and covers a part of the first surface 101, thus providing an effect of reinforcing the surface and the edge of the die, such that the substrate 10 is not easily broken and damaged during the grinding process, and cracks are not easily generated.

The carrier 20 is removed after the thinning process of the second surface 102 of the substrate 10 has been finished. Then, as shown in FIG. 2F, a plurality of electrical channels 30 is formed on each lead pad 10b. In this embodiment, the electrical channel 30 is a metal multi-layer film that is formed on the lead pad 10b by way of evaporation or sputtering. Therefore, the protective layer 11 on the first surface 101 also serves as the passivation layer. Then, as shown in FIG. 2G, a plurality of solder balls 31 is formed on each electrical channel 30, wherein a soldering layer is first formed on the electrical channel 30 by evaporation, electroplating, or printing etc, and then, the solder balls 31 are formed by ball placement or bumping processes. The electrical channel 30 is used to enhance the adhesiveness with the ball 31 and the lead pad 10b, and also to avoid generating the brittle intermetallic compound. The solder ball 31 is used for the subsequent flip chip packaging process. Finally, each notch 10a is diced to form a plurality of chip level substrates 10, as shown in FIG. 1.

In the first embodiment, the diced chip level substrate 10 has a plurality of lead pads 10b, a plurality of electrical channels 30, and a plurality of solder balls 31, but the present invention is not limited, it may also have a single lead pad 10b, an electrical channel 30, and a solder ball 31. Moreover, the wafer level packaging structure of the first embodiment is illustrated in detail below with reference to FIG. 2G, and it includes a wafer level substrate 10 and a protective layer 11. The substrate 10 has a first surface 101, a second surface 102, and a plurality of notches 10a. The protective layer 11 is located on the first surface 101 and in each notch 10a, and it is exposed at the second surface 102 through each notch 10a. Moreover, the protective layer 11 located on the first surface 101 connects to the protective layer 11 in each notch 10a and covers the area of the first surface 101 except the lead pads 10b. Moreover, the wafer level packaging structure of the first embodiment further includes the electrical channel 30 located on each lead pad 10b, and the solder ball 31 located on each electrical channel 30.

Moreover, the chip level packaging structure of the first embodiment may be applied in the CiSP process, and the wrapping of the protective layer 11 provides a preferred stress buffering, so as to avoid the breaking of the internal chip caused by the stress during the burying process or when the outside of the packaging is deformed. The buried chip level packaging structure of the present invention further includes a carrier (not shown) for the chip 10 wrapped with the protective layer 11 to be buried therein, and the metal lead is used to transfer signals of the chip 10 out of the carrier.

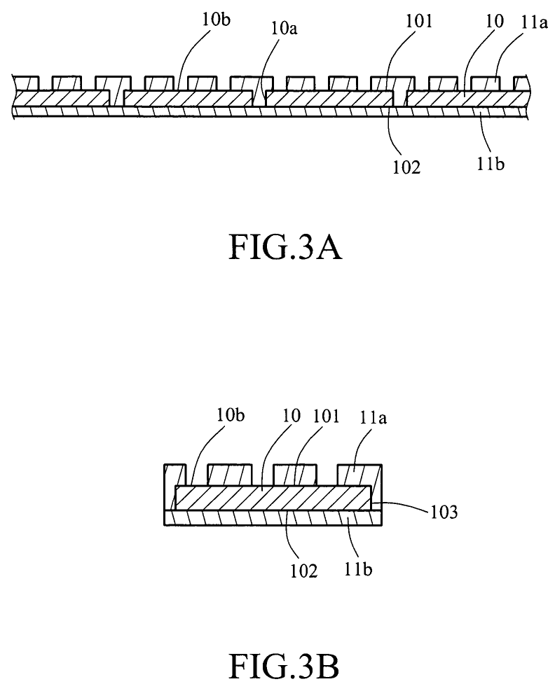

Referring to FIG. 3A and FIG. 3B, the packaging method of the second embodiment of the present invention is illustrated in detail. As shown in FIG. 3A, a wafer level substrate 10 having a first surface 101 and a second surface 102 is provided. Next, a plurality of notches 10a is formed on the first surface 101, and a first protective layer 11a is formed on the first surface 101 and in each notch 10a. The first protective layer 11a fills up the cracks generated while dicing the notches 10a, prevents the cracks from being continuously expanded during the subsequent packaging process and thereby achieving the function of protecting the die. Next, the first protective layer 11a is etched to expose a plurality of the lead pads 10b of the first surface 101. Then, the second surface 102 of the substrate 10 is thinned, such that the first protective layer 11a in the notch 10a is exposed at the second surface 102. The protective layer 11a fills up the cracks generated while dicing the notch 10a, and covers a part of the first surface 101, thus providing an effect of reinforcing the surface and the edge of the die, such that the substrate 10 is not easily broken and damaged during the grinding process, and cracks are not easily generated. The steps may be obtained with reference to the method described in the first embodiment.

Next, a second protective layer 11b is formed on the second surface 102, and connects to the first protective layer 11a in each notch 10a. In this embodiment, both the first protective layer 11a and the second protective layer 11b are high molecular polymer layers. At this time, the patterns of the first protective layer 11a and the second protective layer 11b are that, the first protective layer 11a on the first surface 101 connects to the first protective layer 11a in each notch 10a and covers the area of the first surface 101 except the lead pad 10b, and the second protective layer 11b totally covers the second surface 102. Finally, each notch 10a is diced to form a plurality of chip level substrates 10, as shown in FIG. 3B.

As shown in FIG. 3A, the wafer level packaging structure of the second embodiment includes a wafer level substrate 10, a first protective layer 11a, and a second protective layer 11b. The first protective layer 11a on the first surface 101 connects to the first protective layer 11a in each notch 10a and covers the area of the first surface 101 except the lead pad 10b. The second protective layer 11b is located on the second surface 102, connects to the first protective layer 11a through each notch 10a, and totally covers the second surface 102. The first protective layer 11a and the second protective layer 11b are used to fill up the gaps generated while dicing the notch 10a and grinding the second surface 102, so as to reinforce the die structure, and thereby preventing the cracks of the chip from being expanded and preventing the chip from being damaged due to the collision during the transportation process. Moreover, the chip level packaging structures are formed after dicing the wafer level packaging structure, as shown in FIG. 3B, wherein the first protective layer 11a is located on the first surface 101 and the edge 103; the second protective layer 11b is located on the second surface 102, and connects to the first protective layer 11a at the edge 103. At this time, the area of the chip level substrate 10 except the lead pad 10b is wrapped by the first protective layer 11a and the second protective layer 11b. When the substrate 10 with an extremely small thickness is flexed under an external force, the wrapping of the first protective layer 11a and the second protective layer 11b provides a preferred stress buffering, thus preventing the cracks from being expanded due to the flexing effect caused by the external force. Therefore, the chip level packaging structure of the present invention may be assembled in a flexible electronic module, and when the flexible electronic module is flexed, the chip level packaging structure is correspondingly flexed with it.

Moreover, similarly to the first embodiment, the electrical channel and the solder ball (not shown) may be further formed on the lead pad 10b in the second embodiment, which are used for the subsequent packaging processes. Therefore, the first protective layer 11a on the first surface 101 also provides the function of a passivation layer.

In addition, the chip level packaging structure of the second embodiment may be applied in the CiSP process, and the wrapping of the first protective layer 11a and the second protective layer 11b provides a preferred stress buffering, so as to avoid the breaking of the internal chip caused by the stress during the burying process or when the outside of the packaging is deformed. Furthermore, the buried chip level packaging structure of the present invention further includes a carrier (not shown) for the chip 10 wrapped with the first protective layer 11a and the second protective layer 11b to be buried therein, and the metal lead is used to transfer signals of the chip 10 out of the carrier.

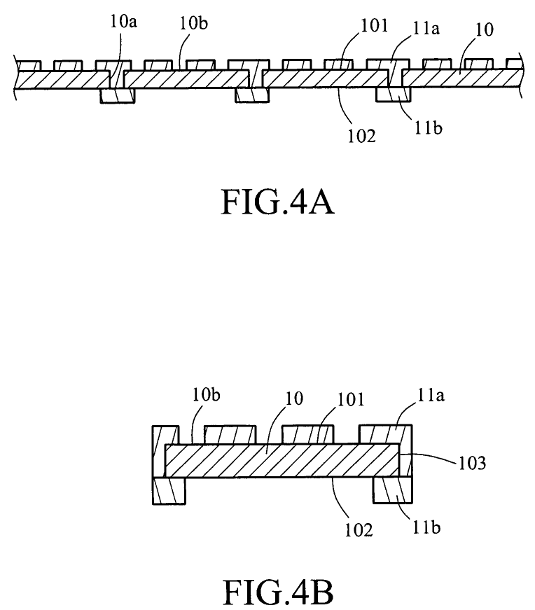

Referring to FIG. 4A and FIG. 4B, the third embodiment of the present invention is illustrated. As shown in FIG. 4A, as mentioned in the above method, a first protective layer 11a is formed on the first surface 101 and in the notch 10a of the wafer level substrate 10, and a second protective layer 11b is formed on the second surface 102. In this embodiment, the second protective layer 11b is only formed on the second surface 102 around the notch 10a, and the forming method is that, firstly, the high molecular polymer layer is deposited and coated on the second surface 102, then, the pattern of the second protective layer 11b is formed by etching, or the high molecular polymer layer is directly printed or jet printed on the second surface 102, so as to form the pattern of the second protective layer 11b. Finally, each notch 10a is diced to form a plurality of chip level substrates 10, as shown in FIG. 4B. As for the wafer level packaging structure of the third embodiment as shown in FIG. 4A, the first protective layer 11a on the first surface 101 connects to the first protective layer 11a in each notch 10a and covers the area of the first surface 101 except the lead pads 10b. The second protective layer 11b is located on the second surface 102, connects to the first protective layer 11a through each notch 10a, and only covers the second surface 102 around the notch 10a. At this time, the first protective layer 11a and the second protective layer 11b fill up the gaps around the notch 10a, and protect the gaps generated near the notch 10a due to the grinding of the second surface 102, so as to prevent the cracks from being expanded when the substrate 10 is diced from the wafer into the chip, and thereby reinforcing the die edge, and avoiding the die edge from being damaged due to being diced. Moreover, the chip level packaging structure is formed after dicing the wafer level packaging structure, as shown in FIG. 4B, wherein in this embodiment, the second surface 102 only has a second protective layer 11b at the position near the edge 103, thus, not only the die edge is protected from being damaged, but also it is easy for the second surface 102 to dissipate heats when being applied to a high power element. Moreover, similarly to the first embodiment, the electrical channel and the solder ball may be further formed on the lead pad 10b in the third embodiment, which are used for the subsequent packaging process. Therefore, the first protective layer 11a on the first surface 101 also provides the function of a passivation layer. The chip level packaging structure with the protective layer of the third embodiment may be applied in the CiSP process.

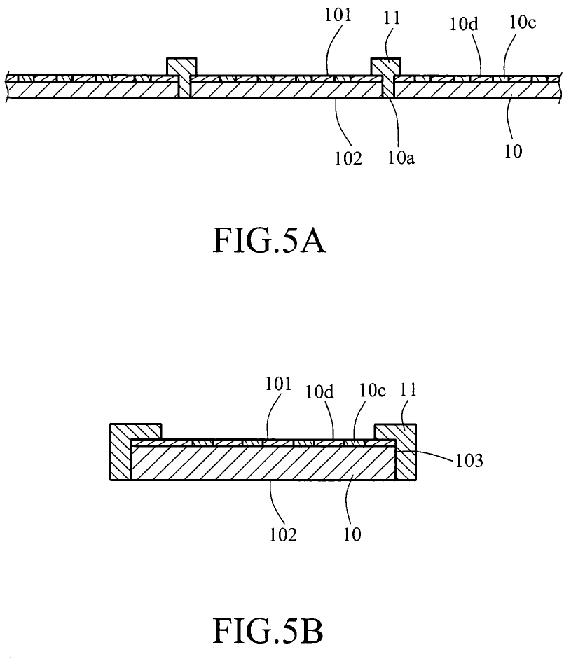

Referring to FIG. 5A and FIG. 5B, the fourth embodiment of the present invention is illustrated. As shown in FIG. 5A, the first surface 101 of the wafer level substrate 10 has a plurality of lead pads 10c and a plurality of passivation layers 10d (the quantity is merely used for illustration herein, but not to limit the present invention). The protective layer 11 is only formed in the notch 10a and on the first surface 101 around the notch 10a, and because the first surface 101 already has the passivation layer 10d, the protective layer 11 only needs to cover around the notch 10a to provide protections. Furthermore, the substrate 10 is diced to make the wafer form chips, as shown in FIG. 5B, wherein the protective layer 11 is only located at the edge 103 and the neighboring first surface 101 of the chip level substrate 10, so as to fill up the gaps of the edge 103 and to reinforce the die edge and thereby protecting it from being damaged. In this embodiment, the protective layer 11 is only required to from around the notch 10a. When the method is integrated in the original process, the original circuit distribution of the substrate 10 is not influenced. Moreover, similarly to the first embodiment, the electrical channel and the solder ball may be further formed on the lead pad 10c in the fourth embodiment, which are used for the subsequent packaging process. The chip level packaging structure with the protective layer of the fourth embodiment may be applied in the CiSP process.

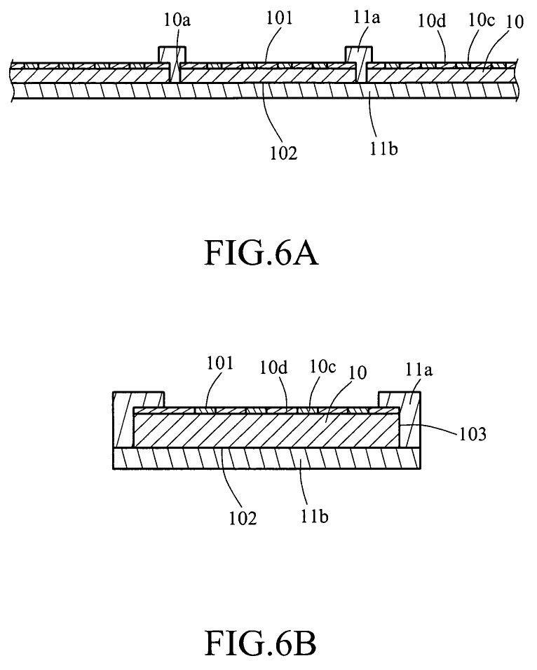

Referring to FIG. 6A and FIG. 6B, the fifth embodiment of the present invention is illustrated. As shown in FIG. 6A, the first surface 101 of the wafer level substrate 10 has a plurality of lead pads 10c and a plurality of passivation layers 10d. The first-protective layer 11a is only formed in the notch 10a and on the first surface 101 around the notch 10a, and because the first surface 101 already has a passivation layer 10d, the protective layer 11 only needs to cover around the notch 10a to provide protections. The second protective layer 11b totally covers the second surface 102, and connects to the first protective layer 11a through the notch 10a. When the substrate 10 with an extremely small thickness is flexed under an external force, the wrapping of the first protective layer 11a and the second protective layer 11b provides a preferred stress buffering, thus preventing the cracks from being expanded due to the flexing effect caused by the external force. Therefore, the chip level packaging structure of the present invention may be assembled in a flexible electronic module, as shown in FIG. 6B, and when the flexible electronic module is flexed, the chip level packaging structure is correspondingly flexed with it. Moreover, in the CiSP process, the wrapping of the first protective layer 11a and the second protective layer 11b provides a preferred stress buffering, so as to avoid the breaking of the internal chip caused by the stress during the burying process or when the outside of the packaging is deformed. The first protective layer 11a is formed around the notch 10a, so as to not influence the original circuit distribution of the substrate 10. Moreover, similarly to the first embodiment, the electrical channel and the solder ball (not shown) are further formed on the lead pad 10c in the fifth embodiment, which are used for the subsequent packaging process.

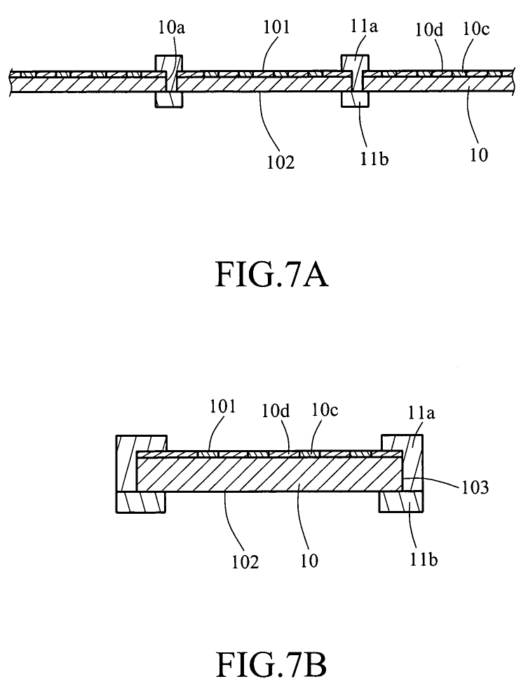

Referring to FIG. 7A and FIG. 7B, the sixth embodiment of the present invention is illustrated. As shown in FIG. 7A, the first surface 101 of the wafer level substrate 10 has a plurality of lead pads 10c and a plurality of passivation layers 10d. The first protective layer 11a is only formed in the notch 10a and on the first surface 101 around the notch 10a, and because the first surface 101 already has the passivation layer 10d, the protective layer 11 only needs to cover around the notch 10a to provide protections. The second protective layer 11b only needs to cover the second surface 102 around the notch 10a. At this time, the first protective layer 11a and the second protective layer 11b fill up the gaps around the notch 10a, and protect the gaps generated around the notch 10a due to the grinding of the second surface 102, so as to prevent the cracks from being expanded while the substrate 10 is diced from the wafer to the chip, and thereby reinforcing the die edge and protecting the die edge from be damaged due to being diced. Moreover, as shown in FIG. 7B, the second surface 102 only has the second protective layer 11b at the position near the edge 103, thus, not only the die edge is protected from being damaged, but also it is easy for the second surface 102 to dissipate heats when being applied to a high power element. The first protective layer 11a is formed around the notch 10a, so as to not influence the original circuit distribution of the substrate 10. Moreover, similarly to the first embodiment, the electrical channel and the solder ball may be further formed on the lead pad 10c in the sixth embodiment, which are used for the subsequent packaging process. The chip level packaging structure with the protective layer of the sixth embodiment may be applied in the CiSP process.

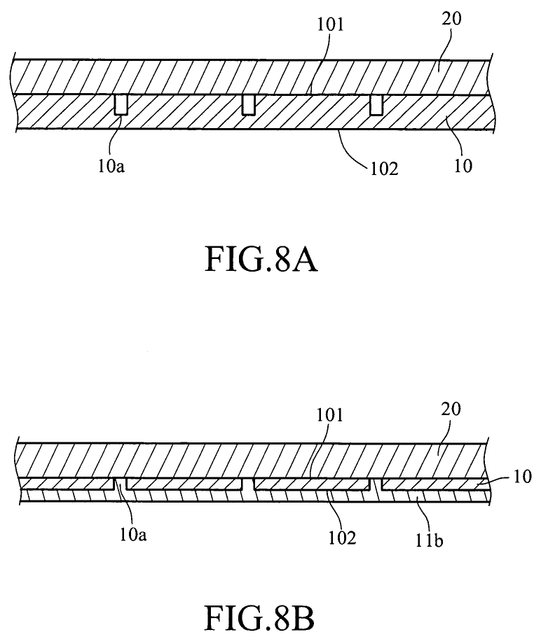

Referring to FIG. 8A and FIG. 8B, the seventh embodiment of the present invention is illustrated. As shown in FIG. 8, the largest difference between this embodiment and the above embodiments is that, the first protective layer 11a is not coated on the first surface 101 in this embodiment, that is, after a plurality of notches 10a has been formed on the first surface 101 of the wafer level substrate 10 (as shown in FIG. 2B), the carrier 20 is used to absorb the first surface 101 of the substrate 10, and then, the second surface 102 is used to thin the substrate 10 by way of grinding or etching. As shown in FIG. 8B, when the second surface 102 is grinded or etched until the plurality of notches 10a are exposed out of the second surface 102, the second protective layer 11b is totally coated on the second surface 102 and fills in the plurality of notches. Thus, the second protective layer 11b of this embodiment fills up the cracks generated while dicing the notch 10a and the defects generated while grinding or etching the second surface 102. Definitely, the wafer level packaging structure of this embodiment may be applied to the CiSP process, similar to that of the above embodiments, and it may also dice the notch 10a to form the chip level packaging structure, and the repeated steps are not illustrated herein.

To sum up, in the packaging structure with protective layers and packaging method thereof according to the present invention, the protective layer formed by a polymer is filled or covered around the die, so as to reinforce the mechanical strength of the edge and the side wall of the die. Moreover, the polymer is filled in the predicing line to form a protective layer, so as to provide protections for the chip and the die during the chip grinding process. The protective layer provides the thinned die with a preferred stress buffering when the thinned die is flexed. Additionally, the polymer is filled or covered around the die to form a protective layer, so as to provide preferred protections for the chip during the CiSP process. Moreover, the chip level packaging structure of the present invention is assembled on the substrate of a flexible electronic module, and when the flexible electronic module is flexed, the thinned die is correspondingly flexed with it. According to the required application of the chip, different patterns of the protective layer may be formed, so as to provide the most appropriate protecting manner.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A wafer level packaging method, comprising:
providing a wafer having a first surface and a second surface;
forming at least one notch on the first surface;
forming a first protective layer on the first surface and in each notch; and
thinning the second surface so as to make the first protective layer in each notch be exposed at the second surface.

2. The wafer level packaging method as claimed in claim 1, further comprising:
dicing each notch to form at least one chip.

3. The wafer level packaging method as claimed in claim 2, further comprising:
performing a chip in substrate package (CiSP) process for each chip.

4. The wafer level packaging method as claimed in claim 1, further comprising:
performing an etching process to the first protective layer, such that a plurality of electrical channels is formed in the first protective layer.

5. The wafer level packaging method as claimed in claim 4, further comprising:
soldering a plurality of solder balls on the plurality of electrical channels.

6. The wafer level packaging method as claimed in claim 1, wherein the first protective layer is a high molecular polymer layer.

7. The wafer level packaging method as claimed in claim 1, further comprising:
forming a second protective layer on the second surface, for connecting to the first protective layer in each notch.

8. The wafer level packaging method as claimed in claim 7, further comprising:
dicing each notch to form at least one chip.

9. The wafer level packaging method as claimed in claim 8, further comprising:
performing a CiSP process for each chip.

10. The wafer level packaging method as claimed in claim 7, wherein the second protective layer is a high molecular polymer layer.

11. A wafer level packaging method, comprising:
providing a wafer, having a first surface and a second surface;
forming at least one notch on the first surface;
providing a carrier to absorb the first surface;
thinning the second surface, such that each notch layer is exposed at the second surface; and
forming a protective layer on the second surface and in each notch.

12. The wafer level packaging method as claimed in claim 11, further comprising:
dicing each notch to form at least one chip.

13. The wafer level packaging method as claimed in claim 12, further comprising:
performing a chip in substrate package (CiSP) process for each chip.

14. The wafer level packaging method as claimed in claim 11, wherein the protective layer is a high molecular polymer layer.

15. A wafer level packaging structure, comprising:
a wafer having a first surface, a second surface, and at least one notch; and
a first protective layer located on the first surface and in each notch, and being exposed at the second surface through each notch.

16. The wafer level packaging structure as claimed in claim 15, wherein the first protective layer located on the first surface connects to the first protective layer in each notch.

17. The wafer level packaging structure as claimed in claim 15, wherein the first protective layer located on the first surface at least covers a part of the area of the first surface.

18. The wafer level packaging structure as claimed in claim 15, wherein the first surface has at least one lead pad.

19. The wafer level packaging structure as claimed in claim 18, further comprising at least an electrical channel located on each lead pad.

20. The wafer level packaging structure as claimed in claim 19, further comprising at least one solder ball located on each electrical channel.

21. The wafer level packaging structure as claimed in claim 15, wherein the first protective layer is a high molecular polymer layer.

22. The wafer level packaging structure as claimed in claim 15, further comprising a second protective layer located on the second surface and connected to the first protective layer through each notch.

23. The wafer level packaging structure as claimed in claim 22, wherein the second protective layer at least covers a part of the area of the second surface.

24. The wafer level packaging structure as claimed in claim 22, wherein the second protective layer is a high molecular polymer layer.

25. A chip level packaging structure, comprising:
a chip having a first surface and a second surface; and
a first protective layer located on the first surface and at least an edge of the chip that connects the first surface with the second surface.

26. The chip level packaging structure as claimed in claim 25, further comprising a carrier, wherein the chip wrapped with the first protective layer is embedded into the carrier.

27. The chip level packaging structure as claimed in claim 25, wherein the first surface has at least one lead pad.

28. The chip level packaging structure as claimed in claim 27, further comprising at least an electrical channel located on the lead pad.

29. The chip level packaging structure as claimed in claim 28, further comprising at least one solder ball located on each electrical channel.

30. The chip level packaging structure as claimed in claim 25, wherein the first protective layer is a high molecular polymer layer.

31. The chip level packaging structure as claimed in claim 25, further comprising a second protective layer located on the second surface of the chip and connected to the first protective layer located at the edge.

32. The chip level packaging structure as claimed in claim 31, further comprising a carrier, wherein the chip wrapped with the first and second protective layers is embedded into the carrier.

33. The chip level packaging structure as claimed in claim 31, wherein the second protective layer at least covers a part of the area of the second surface.

34. The chip level packaging structure as claimed in claim 31, wherein the second protective layer is a high molecular polymer layer.
